(19) United States
(12) Patent Application Publication
(10) Pub. No.: US 2016/0099391 A1
(43) Pub. Date: Apr. 7, 2016

(54) LIGHT EMITTING DEVICE

(71) Applicant: SAMSUNG ELECTRONICS CO., LTD., Suwon-si (KR)

(72) Inventors: Se Hwan AN, Seoul (KR); Han Hyoung KIM, Ansan-si (KR); Suk Ho JUNG, Hwaseong-si (KR)

(21) Appl. No.: 14/733,942

(22) Filed: Jun. 8, 2015

(30) Foreign Application Priority Data
Oct. 2, 2014 (KR) 10-2014-0133455

(51) Int. Cl. H01L 33/58; H01L 33/56; H01L 27/15; H01L 33/50

(52) U.S. Cl. CPC H01L 33/58; H01L 33/507; H01L 33/56; H01L 27/156; H01L 2933/0091

(57) ABSTRACT

A light emitting device includes: a mounting board; an adhesive member disposed on the mounting board and having a first surface adjacent to the mounting board and a second surface opposing the first surface; and a light emitting element disposed on the second surface of the adhesive member. The second surface of the adhesive member may have a first region on which the light emitting element is disposed and a second region on which a scattering pattern is provided to scatter light emitted by the light emitting element.

### CROSS-REFERENCE TO RELATED APPLICATION

This application claims the priority and benefit of Korean Patent Application No. 10-2014-0133455 filed on Oct. 2, 2014, with the Korean Intellectual Property Office, the disclosure of which is incorporated herein by reference.

### BACKGROUND

The present disclosure relates to a light emitting device.

Semiconductor light emitting devices emit light through recombination of electrons and holes when power is applied thereto, and are commonly used as light sources due to various advantages thereof such as low power consumption, high levels of luminance, compactness, and the like. In particular, after the development of nitride light emitting devices, the utilization thereof has been greatly expanded and such light emitting devices are commonly employed as light sources in the backlight units of display devices, general lighting devices, the headlights of vehicles, and the like. In this technical field, an attempt to improve the luminous efficiency of light emitting devices using semiconductor light emitting devices has been being made.

### SUMMARY

An aspect of the present disclosure may provide a light emitting device having improved luminous efficiency.

According to an aspect of the present disclosure, a light emitting device may include: a mounting board; an adhesive member disposed on the mounting board and having a first surface adjacent to the mounting board and a second surface opposing the first surface; and a light emitting element disposed on the second surface of the adhesive member. The second surface of the adhesive member may have a first region on which the light emitting element is disposed and a second region on which a scattering pattern is provided to scatter light emitted by the light emitting element.

The scattering pattern may include an uneven surface having irregular surface roughness.

The surface roughness (RMS) of the uneven surface may range from approximately 0.1 μm to 1.5 μm.

The scattering pattern may be extended in a direction from one side of the second surface to another side thereof, and include a protrusion pattern and a recess pattern which are alternately arranged.

At least one of an upper portion of the protrusion pattern and a lower portion of the recess pattern may have at least one of a flat surface and a curved surface.

An upper portion of the protrusion pattern may have a pointed edge.

A lower portion of the recess pattern may have a V-like recess.

At least one of an upper portion of the protrusion pattern and a lower portion of the recess pattern may include an uneven surface having irregular surface roughness.

The scattering pattern may include an embossing pattern disposed on the second surface, the embossing pattern having at least one of a polypyramidal shape, a truncated polypyramidal shape, a conical shape, a truncated conical shape, and a dome shape.

The scattering pattern may include an intaglio pattern disposed on the second surface, the intaglio pattern having at least one of a polypyramidal shape, a truncated polypyramidal shape, a conical shape, a truncated conical shape, and a dome shape.

The adhesive member may include at least one material selected from the group consisting of an epoxy resin, a silicone resin, an acrylic resin, an oxetane resin, and combinations thereof.

The light emitting device may further include an encapsulation part disposed on the mounting board and encapsulating the light emitting element.

The encapsulation part may include a wavelength conversion material converting a wavelength of light emitted from the light emitting element to a different wavelength.

A material of the encapsulation part and a material of the adhesive member may have different refractive indices.

According to another aspect of the present disclosure, light emitting device may include: a mounting board; a light emitting element disposed on the mounting board; and an adhesive member disposed between the mounting board and the light emitting element, and having a mounting portion on which the light emitting element is mounted and a peripheral portion which is disposed around the mounting portion. A scattering pattern may be provided on the peripheral portion to scatter light emitted by the light emitting element.

According to still another aspect of the present disclosure, light emitting device may include: a mounting board; a light emitting element disposed on the mounting board; and an adhesive member disposed between the mounting board and the light emitting element. A peripheral portion of the adhesive member that is not covered by the light emitting element may include a scattering pattern.

A portion of the adhesive member that is covered by the light emitting element may have a surface roughness different from that of the peripheral portion of the adhesive member.

A thickness of the peripheral portion of the adhesive member may vary in a direction crossing the light emitting device.

The adhesive member may include at least one material selected from the group consisting of an epoxy resin, a silicone resin, an acrylic resin, an oxetane resin, and combinations thereof.

The light emitting device may further include an encapsulation part disposed on the mounting board and covering the light emitting element and the adhesive layer. A material of the encapsulation part and a material of the adhesive member may have different refractive indices.

### BRIEF DESCRIPTION OF DRAWINGS

The above and other aspects, features and advantages of the present disclosure will be more clearly understood from the following detailed description taken in conjunction with the accompanying drawings, in which:

FIG. 1 is a perspective view of a light emitting device according to an exemplary embodiment in the present disclosure;

FIG. 2 is a cross-sectional view of the light emitting device illustrated in FIG. 1, taken along line I-I′;

FIG. 3 is a perspective view of a modified example of the light emitting device illustrated in FIG. 1, according to an exemplary embodiment in the present disclosure;

FIG. 4 is an enlarged perspective view of region R illustrated in FIG. 3;

FIGS. 5A through 5G are perspective views of modified examples of an adhesive member illustrated in FIGS. 3 and 4, according to exemplary embodiments in the present disclosure;

FIG. 6 is a perspective view of a modified example of the light emitting device illustrated in FIG. 1, according to an exemplary embodiment in the present disclosure;

FIGS. 7A through 7E are views of examples of an embossing pattern that may be employable as a scattering pattern of an adhesive member illustrated in FIG. 6, according to exemplary embodiments in the present disclosure;

FIG. 8 is a perspective view of a modified example of the light emitting device illustrated in FIG. 1, according to an exemplary embodiment in the present disclosure;

FIGS. 9A through 9E are views of examples of an intaglio pattern that may be employable as a scattering pattern of an adhesive member illustrated in FIG. 8, according to exemplary embodiments in the present disclosure;

FIG. 10 is a perspective view of a light emitting device according to an exemplary embodiment in the present disclosure;

FIG. 11 is a cross-sectional view of a light emitting device according to an exemplary embodiment in the present disclosure;

FIG. 12 is a flowchart illustrating a method of manufacturing an adhesive member according to an exemplary embodiment in the present disclosure;

FIGS. 13 through 16 are views illustrating a method of manufacturing a light emitting device according to an exemplary embodiment in the present disclosure;

FIGS. 17 and 18 are views of examples of a lighting device in which a light emitting device according to an exemplary embodiment is employed;

FIGS. 19 and 20 are views of examples of a backlight unit in which a light emitting device according to an exemplary embodiment is employed; and

FIG. 21 is a view of an example of a headlamp in which a light emitting device according to an exemplary embodiment is employed.

### DETAILED DESCRIPTION

Various embodiments will now be described more fully with reference to the accompanying drawings in which some embodiments are shown. The present disclosure may, however, be embodied in different forms and should not be construed as limited to the embodiments set forth herein. Rather, these embodiments are provided so that this disclosure is thorough and complete and fully conveys the present disclosure to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosure.

Spatially relative terms, such as “beneath,” “below,” “lower,” “above,” “upper” and the like, maybe used herein for ease of description to describe one element's or feature's relationship to another element (s) or feature (s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device maybe otherwise oriented (rotated 90 degrees or at other orientations) and the spatially relative descriptors used herein interpreted accordingly.

The terminology used herein is for the purpose of describing particular embodiments only and is not intended to be limiting of the present disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Meanwhile, when an embodiment can be implemented differently, functions or operations described in a particular block may occur in a different way from a flow described in the flowchart. For example, two consecutive blocks may be performed simultaneously, or the blocks may be performed in reverse according to related functions or operations.

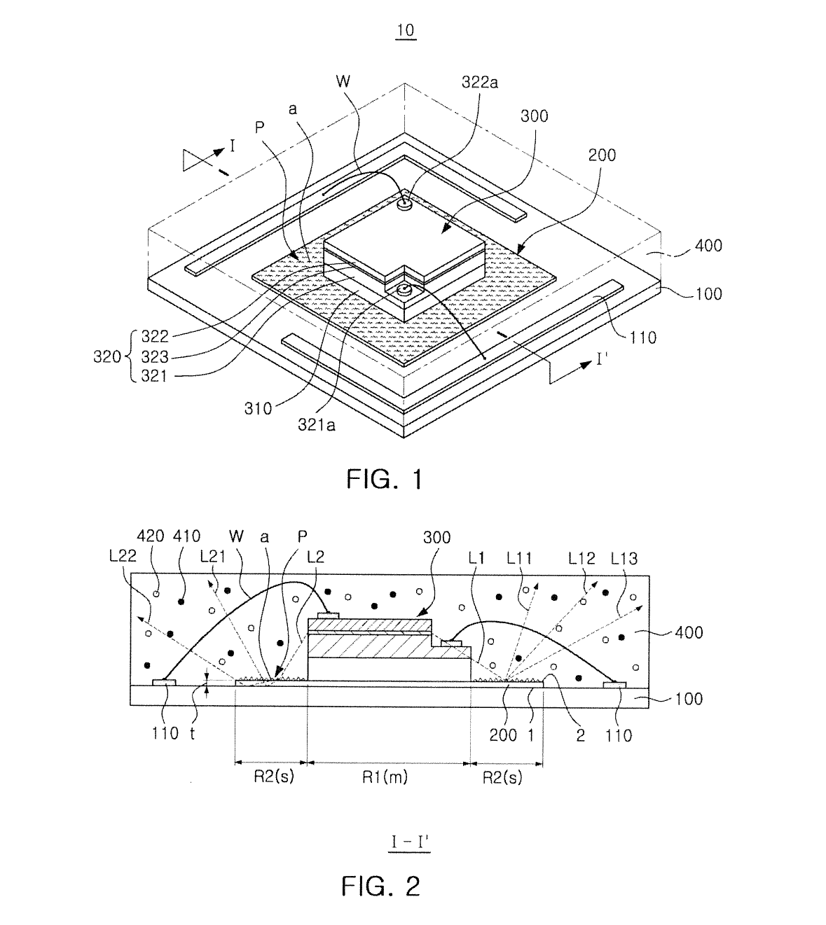

FIG. 1 is a perspective view of a light emitting device according to an exemplary embodiment in the present disclosure. FIG. 2 is a cross-sectional view of the light emitting device illustrated in FIG. 1, taken along line I-I′.

With reference to FIGS. 1 and 2, a light emitting device 10 according to the present exemplary embodiment may include: a mounting board 100; and an adhesive member 200 and a light emitting element 300 disposed on the mounting board 100. The light emitting element 300 may be disposed on the adhesive member 200 so as to be bonded to the mounting board 100 by means of the adhesive member 200. An encapsulation part 400 may be disposed on the mounting board 100 to cover and encapsulate the light emitting element 300.

The mounting board 100 may serve to support the light emitting element 300, and may be provided with a circuit pattern 110 to supply power to drive the light emitting element 300. In this case, as illustrated in FIG. 1, the light emitting element 300 may be mounted on the mounting board 100 provided with the circuit pattern 110 in a chip-on-board (COB) manner. Here, the circuit pattern 110 may be formed on the surface of the mounting board 100 or in the interior of the mounting board 100.

The mounting board 100 may be a printed circuit board (PCB), a metal core printed circuit board (MCPCB), a metal printed circuit board (MPCB), or the like, including the circuit pattern 110. Alternatively, a freely-deformable flexible printed circuit board (FPCB) maybe used therefor. The mounting board 100 is not limited thereto, and may be a board formed of an organic resin material and other organic resin materials containing epoxy, triazine, silicone, polyimide, or the like, a ceramic material such as silicon nitride, AlN, Al₂O₃, or the like, or a metal and a metal compound. The mounting board 100 may be formed of a material having superior heat dissipation and light reflection properties.

The light emitting element 300 may emit light when driving power is applied thereto. For example, the light emitting element 300 may be a semiconductor light emitting element. In this case, the light emitting element 300 may include a substrate 310 and a light emitting structure 320.

The substrate 310 may be provided as a semiconductor growth substrate. For example, the substrate 310 may be formed of an electrically insulating material or a conductive material, such as sapphire, SiC, MgAl₂O₄, MgO, LiAlO₂, LiGaO₂, GaN, or the like.

The light emitting structure 320 may include first and second conductivity type semiconductor layers 321 and 322 with an active layer 323 interposed therebetween. The first and second conductivity type semiconductor layers 321 and 322 may be n-type and p-type semiconductor layers, respectively, but are not limited thereto. In the present exemplary embodiment, the first and second conductivity type semiconductor layers 321 and 322 may have a composition of AlₓIn_{y}Ga_{(1-x-y)}N (where 0≦x≦1, 0≦y≦1, and 0≦x+y≦1). For example, GaN, AlGaN, or InGaN may be used therefor. The active layer 323 interposed between the first and second conductivity type semiconductor layers 321 and 322 may emit light having a predetermined level of energy through electron-hole recombination, and may have a multi-quantum well (MQW) structure in which quantum well layers and quantum barrier layers are alternately stacked. For example, the active layer 323 may have an InGaN/GaN structure.

First and second electrodes 321a and 322a may be disposed on the first and second conductivity type semiconductor layers 321 and 322, respectively. The first and second electrodes 321a and 322a may be electrically connected to the circuit pattern 110 of the mounting board 100 through wires W. The first and second electrodes 321a and 322a may be formed of an electrically conductive material. For example, the first and second electrodes 321a and 322a may be formed of at least one of Ag, Al, Ni, Cr, Cu, Au, Pd, Pt, Sn, W, Rh, Ir, Ru, Mg, Zn, Ti, and alloys thereof.

The adhesive member 200 may be disposed between the light emitting element 300 and the mounting board 100 so as to fix the light emitting element 300 to the mounting board 100. The adhesive member 200 may include an insulating material such as a resin. In detail, the adhesive member 200 may include at least one of an epoxy resin, a silicone resin, an acrylic resin, an oxetane resin, and combinations thereof. The adhesive member 200 may be disposed on the mounting board 100 in a semi-cured state, and after the light emitting element 300 is mounted on the upper surface of the adhesive member 200, the adhesive member 200 may be cured to thereby fix the light emitting element 300 to the mounting board 100. Meanwhile, the material of the adhesive member 200 is not limited to the aforementioned materials, and may be formed of a conductive material such as a metal.

The thickness t of the adhesive member 200 may range, for example, from about 2 μm to about 3 μm so as to effectively have an adhesive function. However, the thickness t of the adhesive member 200 is not limited thereto. When there is a patterned surface, the thickness t refers to the largest thickness measured at the region of the protrusion.

The adhesive member 200 may have a first surface 1 adjacent to the mounting board 100 and a second surface 2 opposing the first surface 1. The light emitting element 300 may be disposed on the second surface 2.

The second surface 2 of the adhesive member 200 may be divided into a first region R1 on which the light emitting element 300 is disposed and a second region R2 corresponding to a region of the second surface 2 other than the first region R1. In detail, the first region R1 may be provided for mounting the light emitting element 300, and may be overlapped with the light emitting element 300 in a thickness direction of the light emitting device 10. The second region R2 may not be overlapped with the light emitting element 300 in the thickness direction of the light emitting device 10. The positions of the first and second regions are not particularly limited, and the first region R1 may be a central region of the second surface 2, while the second region R2 may be provided to surround the first region R1. In this case, the first region R1 may be defined as a mounting portion m on which the light emitting element 300 is mounted, the remaining second region R2 may be defined as a peripheral portion s. The first and second regions R1 and R2 of the second surface 2 may have a surface roughness different from each other. A thickness of the adhesive member 200 in the second region R2 may vary in a direction, for example, a direction along line I-I′, crossing the light emitting device 300.

In the present exemplary embodiment, a scattering pattern P may be formed on the second region R2 so as to scatter light emitted from the light emitting element 300. As described above, in a case in which the second region R2 is provided to surround the first region R1, the second region R2 may be defined as the peripheral portion s and the scattering pattern P may be understood as being disposed on the peripheral portion s.

In the present specification, “the scattering pattern P” refers to a regular or irregular pattern formed on the surface of the adhesive member 200, for example, the region (the second region R2) of the second surface 2 of the adhesive member 200 which is not overlapped with the light emitting element 300 in the thickness direction, so as to scatter light generated by the light emitting element 300 in several directions when the light is partially reflected by and partially transmitted through the surface of the adhesive member 200 after the light reaches the surface of the adhesive member 200. Accordingly, the light generated by the light emitting element 300 and travelling in a direction toward the adhesive member 200 may be scattered by the scattering pattern P in several directions. That is, a portion L1 of the emitted light may be reflected by the second surface 2 of the adhesive member 200, and may be directed by the scattering pattern P in several upward directions (see L11, L12, and L13). In addition, another portion L2 of the emitted light may be transmitted through the second surface 2 of the adhesive member 200 and may be directed by the scattering pattern P in several downward directions, and then may be reflected by the mounting board 100 in several upward directions (see L21 and L22). In this case, as the light generated by the light emitting element 300 is directed in several directions, the amount of light which is confined inside the adhesive member 200 or the encapsulation part 400 due to the total reflection thereof may be reduced, and thus, the luminous efficiency of the light emitting device 10 may be improved. If necessary, the adhesive member 200 may further include a light scattering agent so as to increase the light scattering effect. For example, the light scattering agent may be a material selected from Al₂O₃, TiO₂, and a combination thereof, but is not limited thereto.

In the present exemplary embodiment, the scattering pattern P may include uneven surfaces having irregular surface roughness a. The surface roughness (RMS) of the uneven surface may be selected within an appropriate range in consideration of the convenience of the process and the effective light scattering. For example, the surface roughness (RMS) of the uneven surface may be approximately 0.1 μm to 1.5 μm. The luminance of the light emitting device 10 according to the present exemplary embodiment may be improved by approximately 1.6% as compared with a light emitting device including an adhesive member having no scattering pattern.

The encapsulation part 400 may cover and encapsulate the light emitting element 300. The encapsulation part 400 may include a highly transparent resin so as to allow light generated by the light emitting element 300 to be transmitted therethrough with a minimum loss of light. For example, the encapsulation part 400 may include at least one of an epoxy resin, a silicone resin, a modified silicone resin, a urethane resin, an oxetane resin, an acrylic resin, a polycarbonate resin, a polyimide resin and combinations thereof.

The encapsulation part 400 may be formed of a material having a refractive index different from that of the adhesive member 200. In this case, the light scattering effect may be increased on the basis of a difference between the refractive indices of the encapsulation part 400 and the adhesive member 200. However, the present inventive concept is not limited thereto, and the encapsulation part 400 may be formed of a material having the same refractive index as that of the adhesive member 200.

The encapsulation part 400 may include a wavelength conversion material 410 in order to convert a wavelength of light emitted from the light emitting element 300 into a different wavelength. For example, the wavelength conversion material 410 may include phosphors or quantum dots. In addition, the encapsulation part 400 may include a light scattering agent 420 in order to have an improved light scattering effect. The light scattering agent 420 may be formed of a material having a higher refractive index than the material of the encapsulation part 400. For example, the light scattering agent 420 may be selected from Al₂O₃, TiO₂, and a combination thereof.

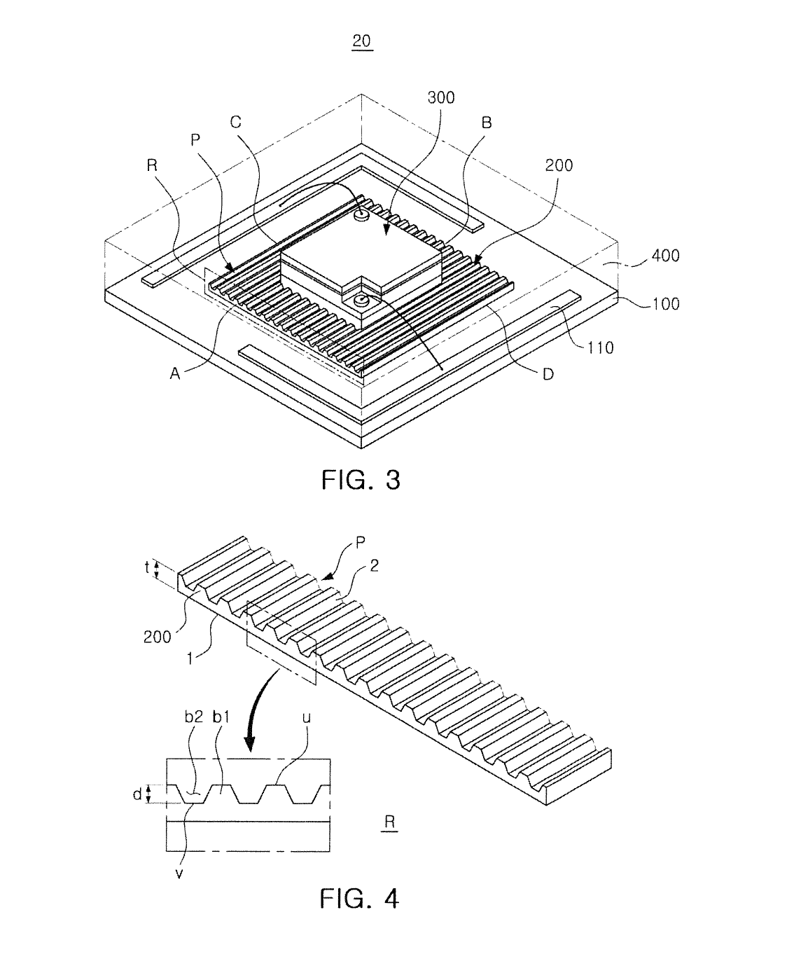

FIG. 3 is a perspective view of a modified example of the light emitting device illustrated in FIG. 1, according to an exemplary embodiment in the present disclosure. FIG. 4 is an enlarged perspective view of region R illustrated in FIG. 3. Hereinafter, a description of the features of a light emitting device 20 according to the present exemplary embodiment the same as those described in the previous exemplary embodiment will be omitted, and different features will be mainly detailed.

With reference to FIGS. 3 and 4, the adhesive member 200 may have the first and second surfaces 1 and 2, and the scattering pattern P may be formed on the second region of the second surface 2. The scattering pattern P may include a protrusion pattern having a plurality of protrusion pattern portions b1 and a recess pattern having a plurality of recess pattern portions b2 extending in a direction from one side A of the second surface 2 of the adhesive member 200 to another side B thereof. In detail, the second surface 2 of the adhesive member 200 may include regions having different thicknesses regularly or irregularly, wherein relatively thick regions and relatively thin regions may be defined as the protrusion pattern portions b1 and the recess pattern portions b2, respectively. In this case, a single recess pattern portion b2 may be disposed between two protrusion pattern portions b1, and a single protrusion pattern portion b1 may be disposed between two recess pattern portions b2. Therefore, the plurality of protrusion pattern portions b1 and the plurality of recess pattern portions b2 may be alternately arranged. Meanwhile, FIG. 3 illustrates that another side B of the second surface 2 to which the protrusion pattern portions b1 and the recess pattern portions b2 are extended opposes the side A of the second surface 2, but the present inventive concept is not limited thereto. Therefore, the protrusion pattern portions b1 and the recess pattern portions b2 may be extended from one side A of the second surface 2 to another side C or D thereof in a diagonal direction.

At least one of an upper portion u of the protrusion pattern portion b1 and a lower portion v of the recess pattern portion b2 may include at least one of a flat surface and a curved surface. For example, as illustrated in FIGS. 3 and 4, each of the upper portion u of the protrusion pattern portion b1 and the lower portion v of the recess pattern portion b2 may include a flat surface. A step d between the protrusion pattern portion b1 and the recess pattern portion b2 may be selected in an appropriate range sufficient to cause the effective light scattering phenomenon. For example, the step d may range from about 0.2 μm to about 2 μm. In addition, the largest thickness t of the adhesive member 200 may range from about 2 μm to about 3 μm, but is not limited thereto.

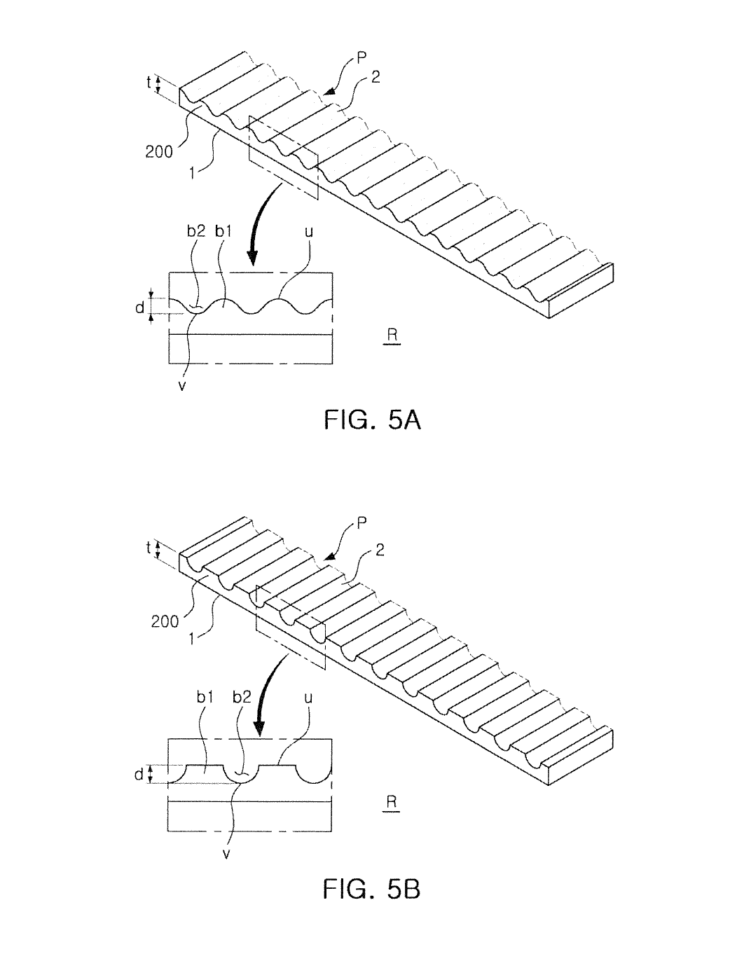

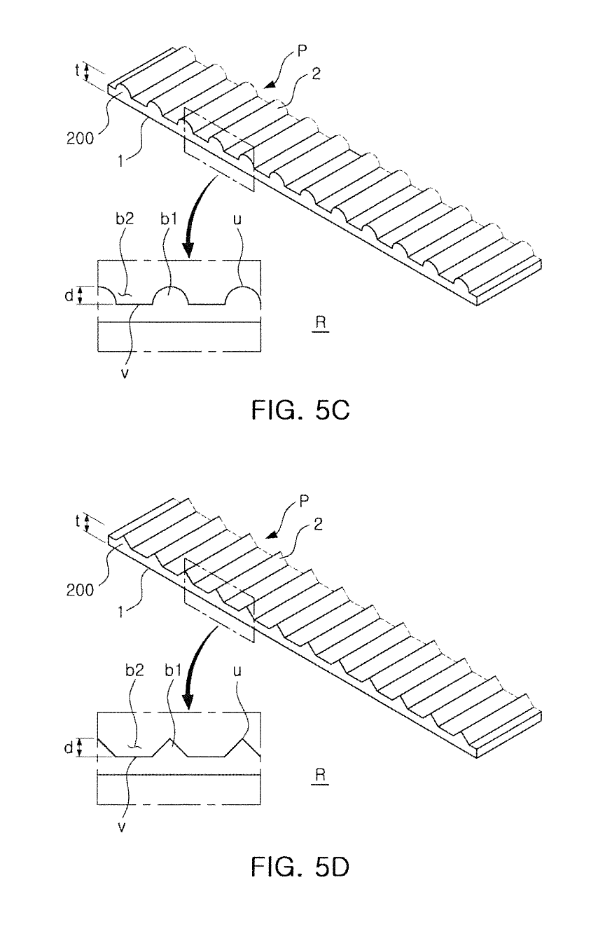

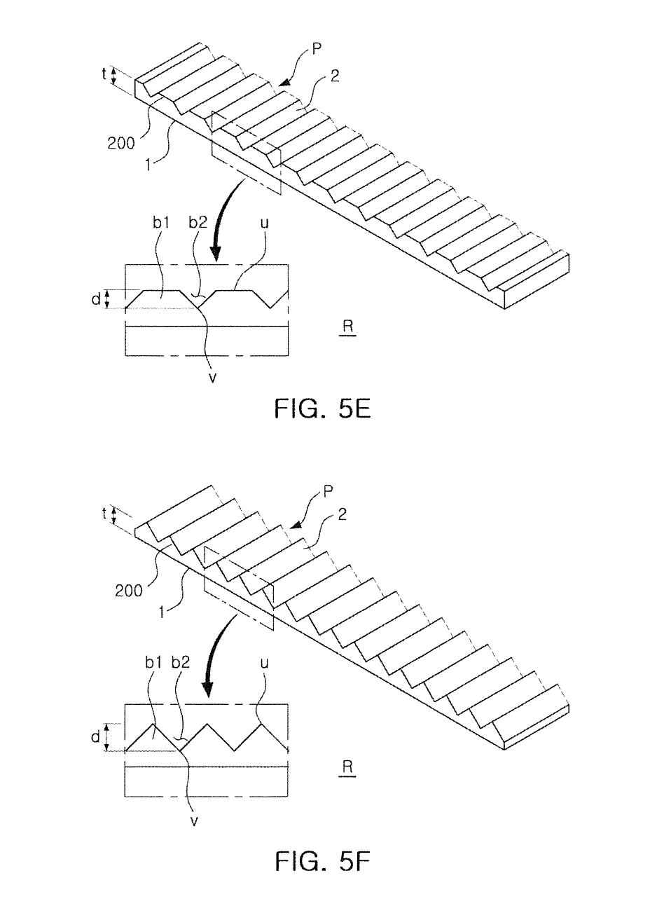

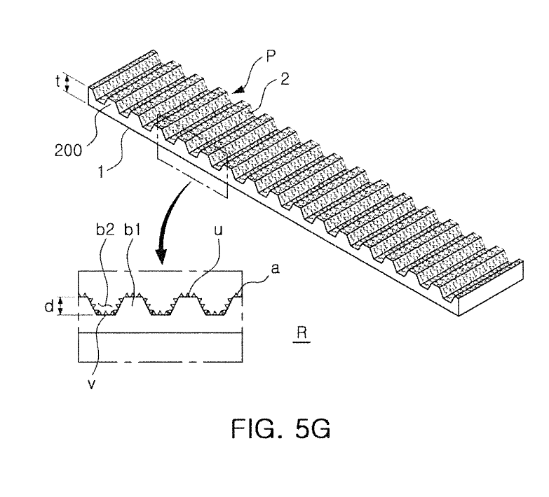

FIGS. 5A through 5G are perspective views of modified examples of the adhesive member illustrated in FIGS. 3 and 4, according to exemplary embodiments in the present disclosure. In detail, each of the perspective views illustrates a portion of the light emitting device corresponding to region R illustrated in FIG. 3.

With reference to FIGS. 5A through 5C, the scattering pattern P formed on the adhesive member 200 may include a protrusion pattern having a plurality of protrusion pattern portions b1 and a recess pattern having a plurality of recess pattern portions b2, and at least one of an upper portion u of the protrusion pattern portion b1 and a lower portion v of the recess pattern portion b2 may include a curved surface. In detail, as illustrated in FIG. 5A, each of the upper portion u of the protrusion pattern portion b1 and the lower portion v of the recess pattern portion b2 may include a curved surface having a predetermined curvature. Alternatively, as illustrated in FIG. 5B, the upper portion u of the protrusion pattern portion b1 may have a flat surface, while the lower portion v of the recess pattern portion b2 may have a curved surface. On the contrary, as illustrated in FIG. 5C, the upper portion u of the protrusion pattern portion b1 may have a curved surface, while the lower portion v of the recess pattern portion b2 may have a flat surface.

As illustrated in FIG. 5D, the upper portion u of the protrusion pattern portion b1 may have a pointed edge, and the lower portion v of the recess pattern portion b2 may have a flat surface. In this case, the scattering pattern P may serve as a triangular prism. However, the present inventive concept is not limited thereto, and the lower portion v of the recess pattern portion b2 may have a curved surface.

In addition, as illustrated in FIG. 5E, the lower portion v of the recess pattern portion b2 may have a V-like recess. Here, the upper portion u of the protrusion pattern portion b1 is illustrated as having a flat surface, but is not limited thereto. The upper portion u of the protrusion pattern portion b1 may have a curved surface, or may have a pointed edge as illustrated in FIG. 5F. The scattering pattern P illustrated in FIG. 5D or 5F may serve as a triangular prism pattern. An interval between adjacent protrusion pattern portions b1 or an interval between adjacent recess pattern portions b2 may be selected in an appropriate range sufficient to cause the effective light scattering phenomenon.

In an exemplary embodiment, the scattering pattern P may be formed by combining the aforementioned examples of the scattering pattern P. For example, as illustrated in FIG. 5G, the scattering pattern P may include the protrusion pattern portion b1 and the recess pattern portion b2, and at least one of the upper portion u of the protrusion pattern portion b1 and the lower portion v of the recess pattern portion b2 may include uneven surfaces having irregular surface roughness a.

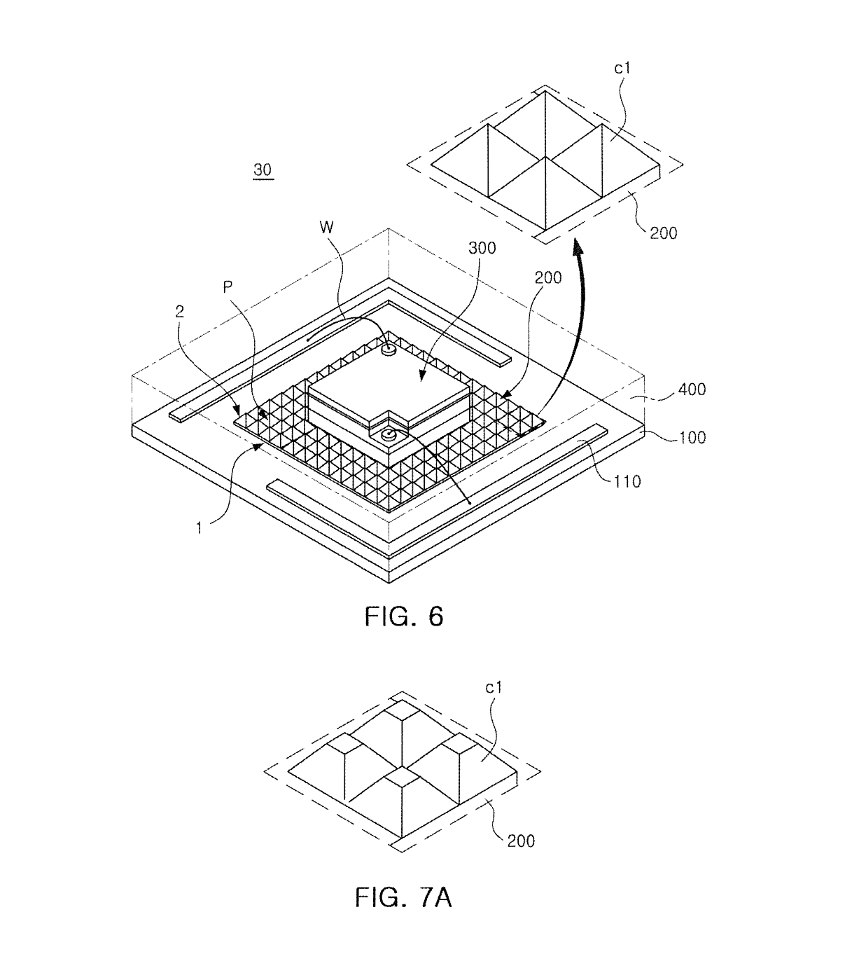

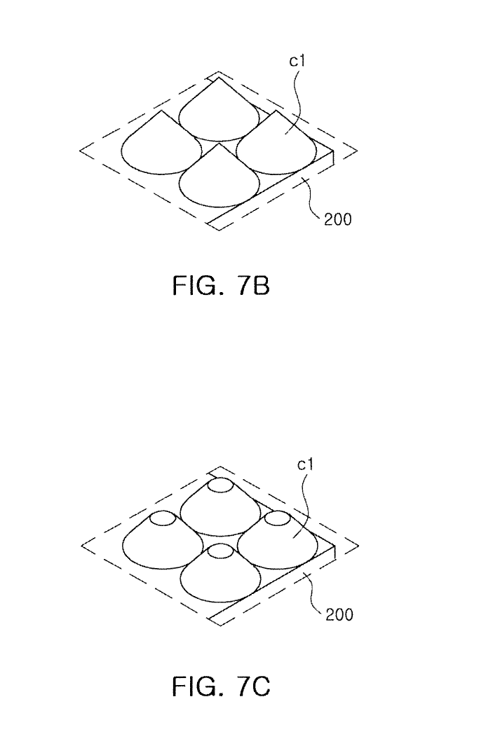

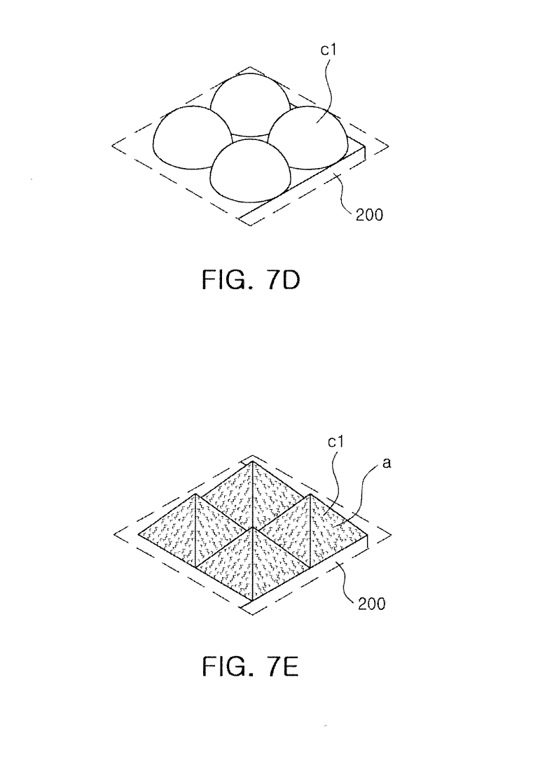

FIG. 6 is a perspective view of a modified example of the light emitting device illustrated in FIG. 1, according to an exemplary embodiment in the present disclosure. FIGS. 7A through 7E are views of examples of an embossing pattern that may be employable as a scattering pattern of an adhesive member illustrated in FIG. 6, according to exemplary embodiments in the present disclosure.

With reference to FIG. 6, a light emitting device 30 may include the adhesive member 200 having the first and second surfaces 1 and 2, and the scattering pattern P may be formed on the second region of the second surface 2. The scattering pattern P may include an embossing pattern having a plurality of embossing pattern portions c1 disposed on the second surface 2. In FIG. 6, the embossing pattern portion c1 is illustrated as having a polypyramidal shape such as a quadrangular pyramidal shape, but is not limited thereto. For example, as illustrated in FIGS. 7A through 7D, the embossing pattern c1 may have at least one of a truncated polypyramidal shape, a conical shape, a truncated conical shape, and a dome shape. In addition, as illustrated in FIG. 7E, the scattering pattern P may include the embossing pattern having the plurality of embossing pattern portions c1, and the embossing pattern portion c1 may include uneven surfaces having irregular surface roughness a.

The plurality of embossing pattern portions c1 may be regularly arranged in rows and columns on the second surface 2 of the adhesive member 200, but are not limited thereto.

The height of the embossing pattern portion c1 of the adhesive member 200 maybe selected within an appropriate range. For example, the height of the embossing pattern portion c1 may range from about 0.2 μm to about 2 μm. In addition, the largest thickness of the adhesive member 200 may range, for example, from about 2 μm to about 3 μm.

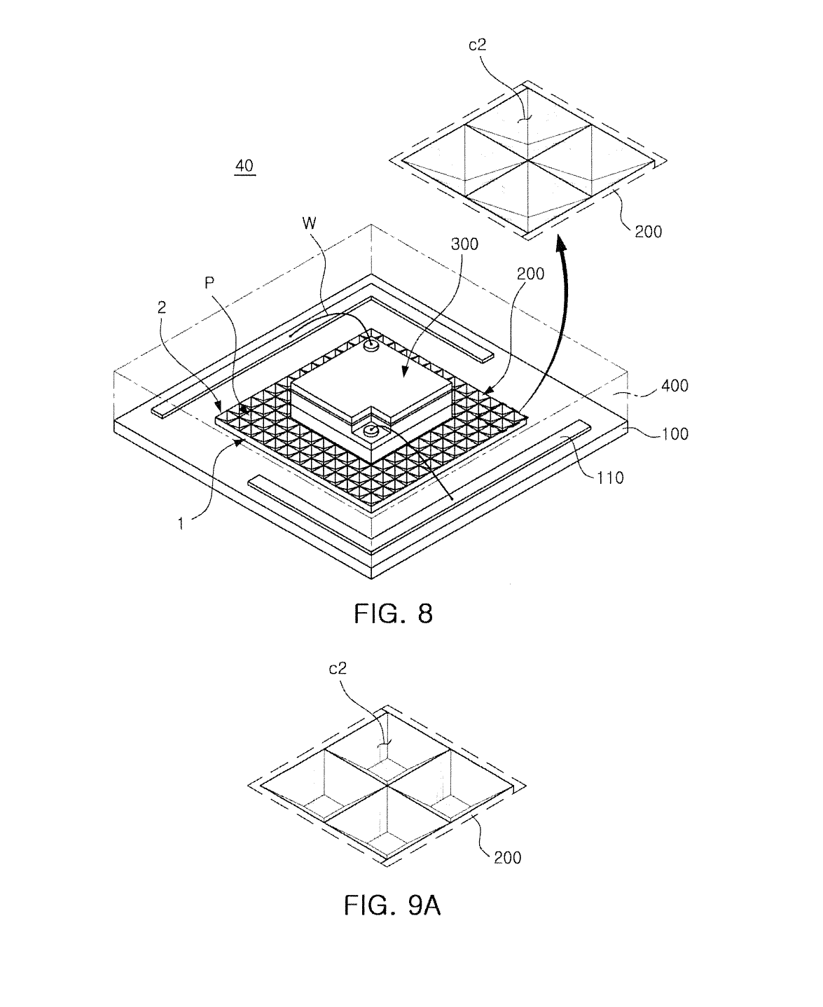

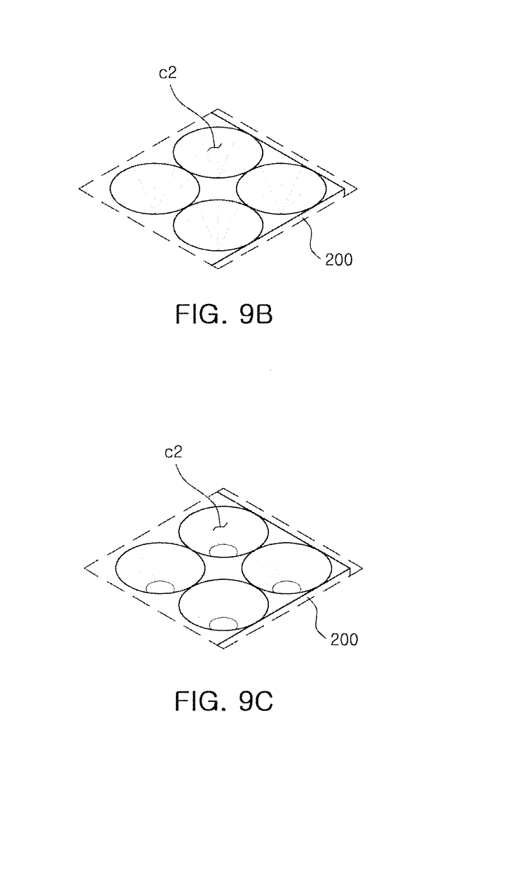

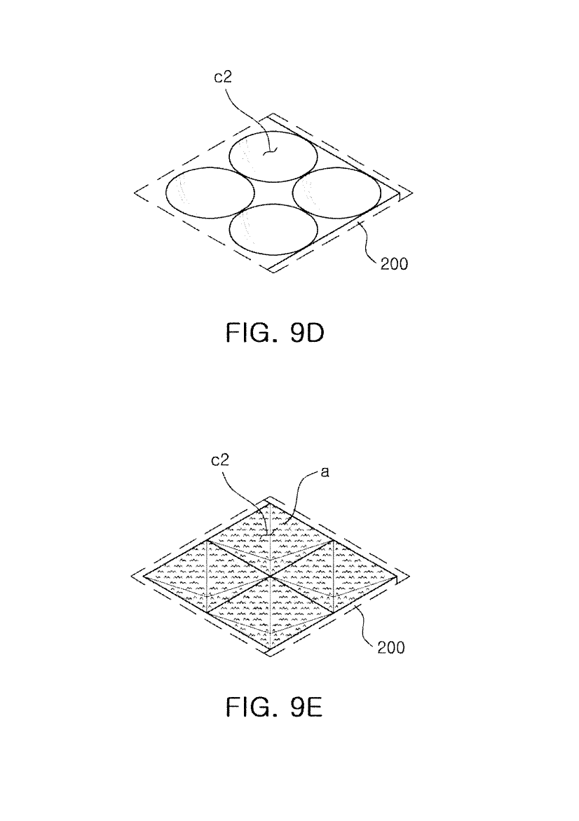

FIG. 8 is a perspective view of a modified example of the light emitting device illustrated in FIG. 1, according to an exemplary embodiment in the present disclosure. FIGS. 9A through 9E are views of examples of an intaglio pattern that maybe employable as a scattering pattern of an adhesive member illustrated in FIG. 8, according to exemplary embodiments in the present disclosure.

With reference to FIG. 8, a light emitting device 40 may include the adhesive member 200 having the first and second surfaces 1 and 2, and the scattering pattern P may be formed on the second region of the second surface 2. The scattering pattern P may include an intaglio pattern having a plurality of intaglio pattern portions c2 disposed on the second surface 2, and the intaglio pattern portion c2 may have a polypyramidal shape. The depth of the intaglio pattern portion c2 may range, for example, from about 0.2 μm to about 2 μm. However, the intaglio pattern portion c2 is not limited thereto, and the intaglio pattern portion c2 may have various shapes. For example, as illustrated in FIGS. 9A through 9D, the scattering pattern P may include the intaglio pattern portion c2 having at least one of a truncated polypyramidal shape, a conical shape, a truncated conical shape, and a dome shape. In addition, as illustrated in FIG. 9E, the intaglio pattern portion c2 may include uneven surfaces having irregular surface roughness a.

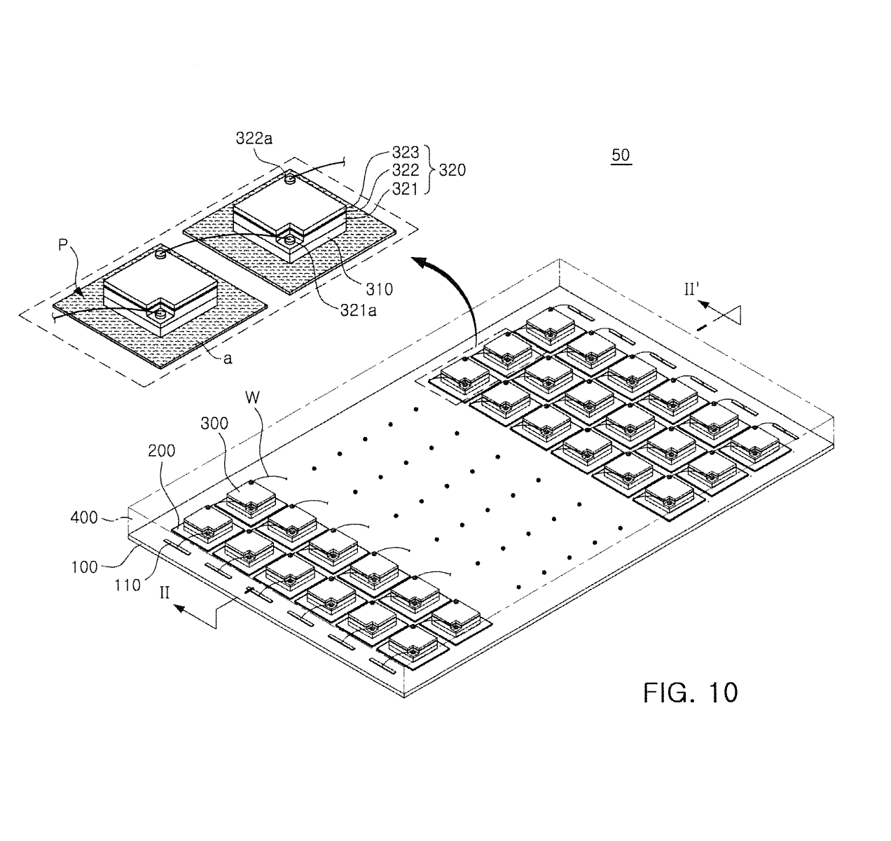

FIG. 10 is a perspective view of a light emitting device according to an exemplary embodiment in the present disclosure.

As illustrated in FIG. 10, a light emitting device 50 may include the plurality of light emitting elements 300 mounted on the mounting board 100. The plurality of adhesive members 200 may be provided between the mounting board 100 and the plurality of light emitting elements 300 in order to bond the light emitting elements 300 to the mounting board 100, respectively. The plurality of light emitting elements 300 may be electrically connected to each other through wires W. The plurality of light emitting elements 300 may be directly connected to each other through wire bonding in a chip-to-chip bonding manner, but the connections thereof are not limited thereto. The mounting board 100 may include the circuit pattern 110. In the present exemplary embodiment, the plurality of light emitting elements 300 may be mounted on the mounting board 100 provided with the circuit pattern 110 in a chip-on-board (COB) manner.

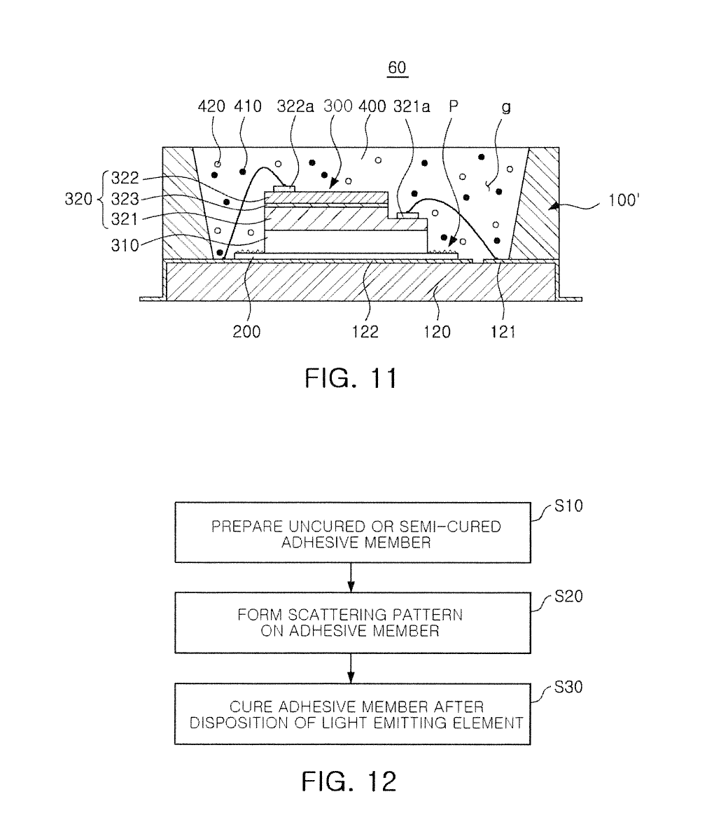

FIG. 11 is a cross-sectional view of a light emitting device according to an exemplary embodiment in the present disclosure.

As illustrated in FIG. 11, a light emitting device 60 according to the present exemplary embodiment may include a mounting board 100′, the adhesive member 200 and the plurality of light emitting elements 300.

In the present exemplary embodiment, the mounting board 100′ may be a package board including a package body 120 and first and second electrode terminals 121 and 122. In this case, the package body 120 is illustrated as having a cavity g which is provided as a region in which the light emitting elements 300 are to be disposed, but is not limited thereto. The package body 120 may be formed of a resin which is opaque and has high reflectivity. For example, the package body 120 may be formed of a polymer resin which is advantageous in injection molding. However, the material of the package body 120 is not limited thereto, and may be formed of various non-conductive materials. The first and second electrode terminals 121 and 122 may be formed of a metal material having high electrical conductivity, and may be electrically connected to the first and second electrodes 321a and 322a of the light emitting elements 300 to transfer driving power which is supplied by an external power source to the light emitting elements 300.

In the present exemplary embodiment, the adhesive member 200 may be disposed on the package body 120, or may be disposed on at least one of the first and second electrode terminals 121 and 122. The adhesive member 200 may fix the light emitting elements 300 disposed thereon to the mounting board 100′.

Hereinafter, a method of manufacturing the adhesive member described in the previous exemplary embodiments and a method of manufacturing a light emitting device using the same will be described.

FIG. 12 is a flowchart illustrating a method of manufacturing an adhesive member, according to an exemplary embodiment in the present disclosure.

With reference to FIG. 12, in the method of manufacturing an adhesive member according to the present exemplary embodiment, an uncured or semi-cured adhesive member may be prepared in S10. In S10, the adhesive member may be an uncured or semi-cured resin. For example, the adhesive member 200 may include at least one of an epoxy resin, a silicone resin, an acrylic resin, an oxetane resin, and combinations thereof.

Next, a scattering pattern may be formed on the adhesive member in S20. The scattering pattern may be a regular or irregular pattern formed on the surface of the adhesive member, so as to scatter light generated by the light emitting elements in several directions, for example, may be the scattering pattern P described in the previous exemplary embodiments.

Then, after the light emitting elements are disposed on the adhesive member on which the scattering pattern is formed, the adhesive member may be cured in S30. For example, the adhesive member may be subjected to a heat treatment in S30.

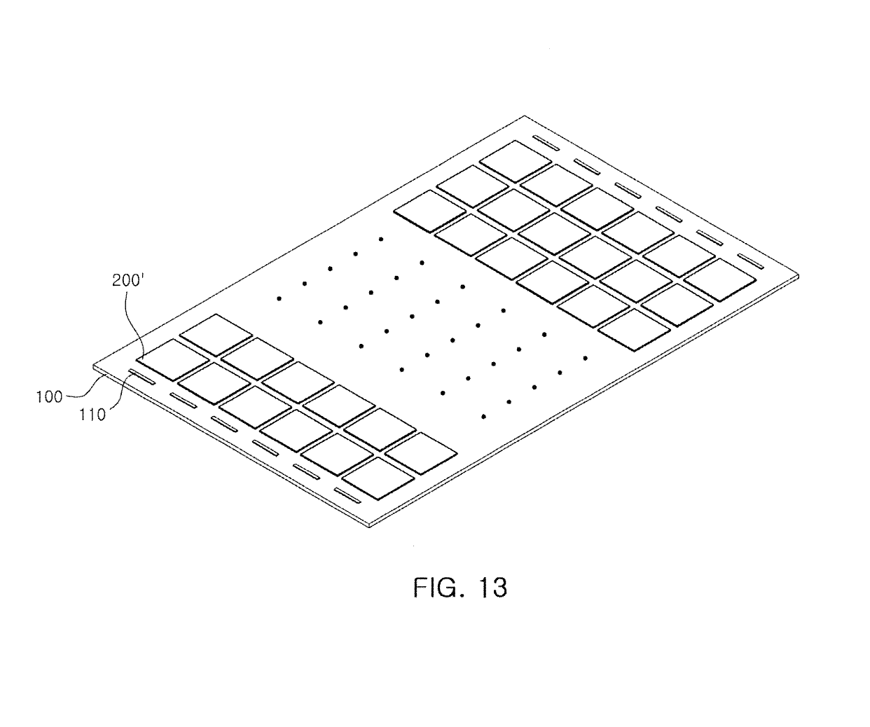

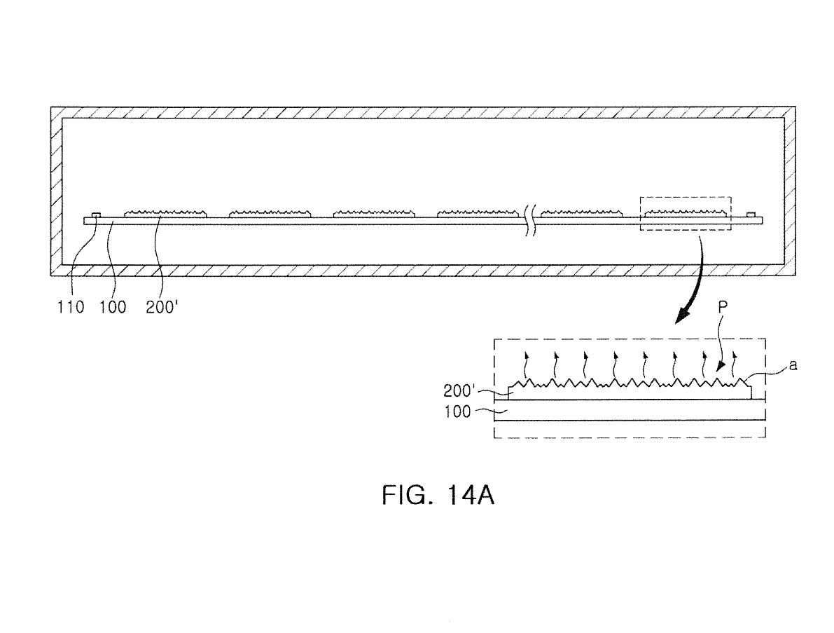

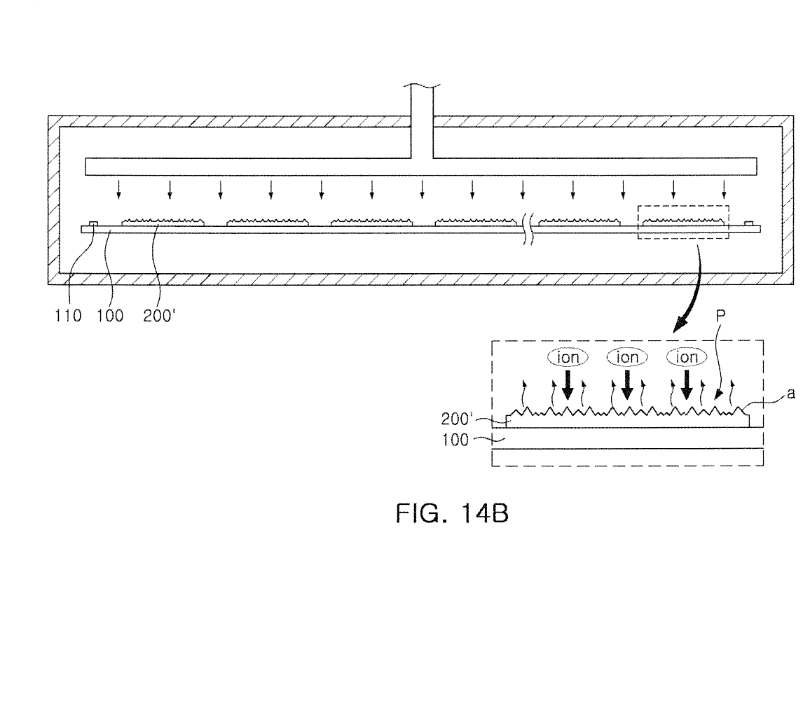

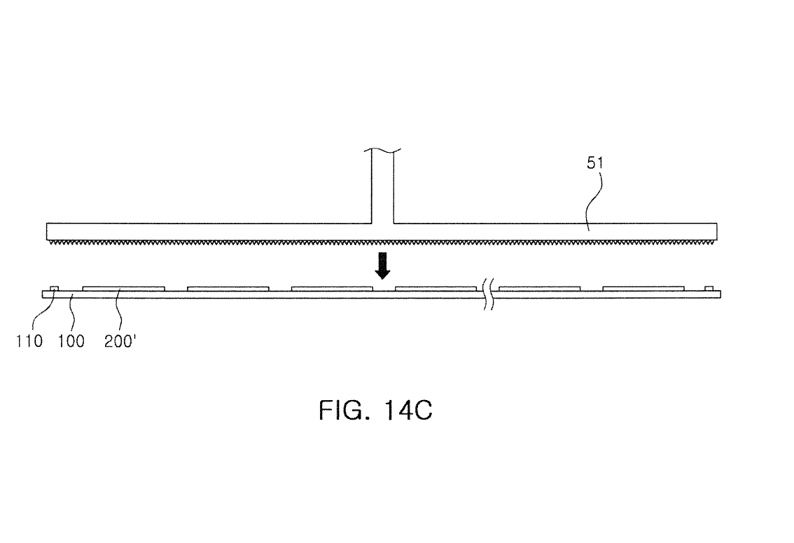

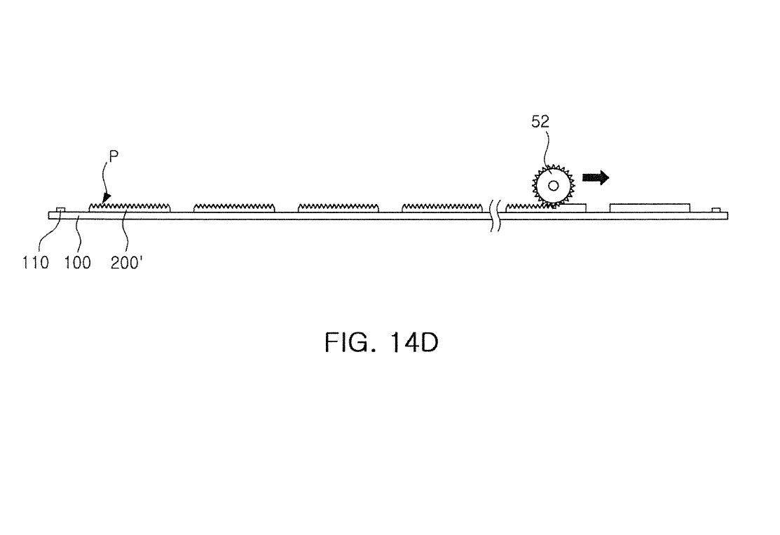

FIGS. 13 through 16 are views illustrating a method of manufacturing a light emitting device according to an exemplary embodiment in the present disclosure. In detail, the views illustrate the method of manufacturing the light emitting device illustrated in FIG. 10, and FIGS. 14A through 14D and FIGS. 15 and 16 are cross-sectional views of the light emitting device illustrated in FIG. 10, taken along line II-II′.

First of all, as illustrated in FIG. 13, a semi-cured adhesive member 200′ maybe disposed on the mounting board 100. The adhesive member 200′ may include a plurality of adhesive members. The largest thickness of the adhesive member 200′ may range, for example, from about 2 μm to about 3 μm so as to effectively have an adhesive function. Here, the adhesive member 200′ may include a semi-cured resin at this stage, which is prior to the formation of the scattering pattern P. The “semi-cured” state refers to a state in which the curing of the resin is not completed but is progressed until treatment or processability thereof is sufficiently facilitated.

Next, the scattering pattern P may be formed on the adhesive member 200′. The method of forming the scattering pattern P on the adhesive member 200′ will be described with reference to FIGS. 14A through 14D.

In the present exemplary embodiment, the scattering pattern P may be formed by vacuum-processing the semi-cured adhesive member 200′. In detail, in a case in which the adhesive member 200′ is vacuum-processed as illustrated in FIG. 14A, bubbles present inside the adhesive member 200′ may be discharged externally to form irregular surface roughness a on the surface of the adhesive member 200′. The uneven surface of the adhesive member 200′ having irregular surface roughness a may be used as the scattering pattern P.

In addition, as illustrated in FIG. 14B, the scattering pattern P may be formed by dry-etching the surface of the adhesive member 200′. For example, the surface of the adhesive member 200′ may be partially etched using a hydrogen plasma or an inert gas plasma to form an uneven surface having irregular surface roughness a. In a case in which the dry-etching is performed at low pressures of several Torr, the bubbles present inside the adhesive member 200′ may be discharged externally to form higher surface roughness a.

Alternatively, the scattering pattern P may be formed by using an imprint lithography method in which a mold 51 having a predetermined pattern is applied to the semi-cured adhesive member 200′ as illustrated in FIG. 14C, or by using a roll-to-roll imprint lithography method in which a roller 52 having predetermined protrusions is used as illustrated in FIG. 14D. In this case, the scattering pattern P may be formed as a regular pattern.

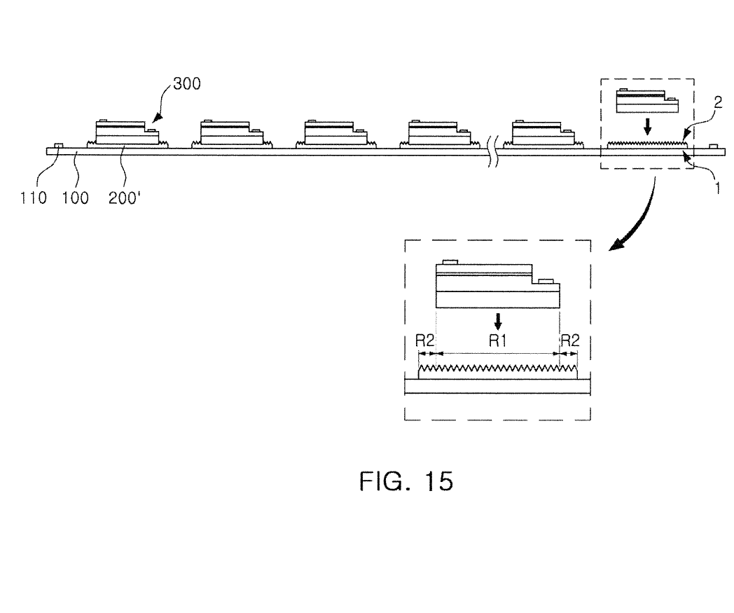

Next, as illustrated in FIG. 15, the light emitting elements 300 may be disposed on the adhesive members 200′ on which the scattering pattern P is formed. Each adhesive member 200′ may have a first surface 1 adjacent to the mounting board 100 and a second surface 2 opposing the first surface 1, and the second surface 2 may be divided into a first region R1 on which the light emitting elements 300 are disposed and a second region R2 corresponding to a region of the second surface 2 other than the first region R1. The first region may be pressed by the light emitting elements 300 disposed thereon so as to be flat while the scattering pattern P is lost. Thereafter, the adhesive members 200′ may be cured.

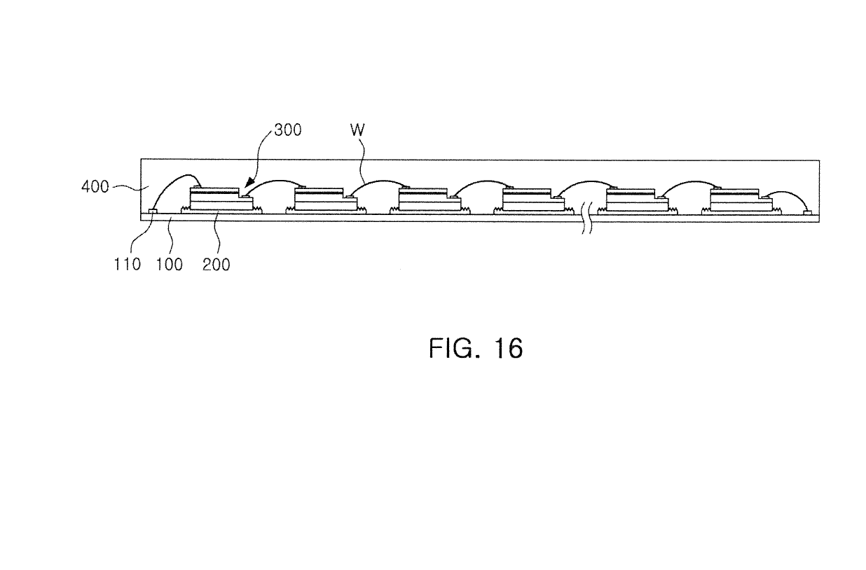

Then, as illustrated in FIG. 16, the light emitting elements 300 and the circuit pattern 110 of the mounting board 100 may be electrically connected to each other by using the wires W and the encapsulation part 400 may be formed to encapsulate the light emitting elements 300. The encapsulation part 400 may include a wavelength conversion material such as phosphors or quantum dots.

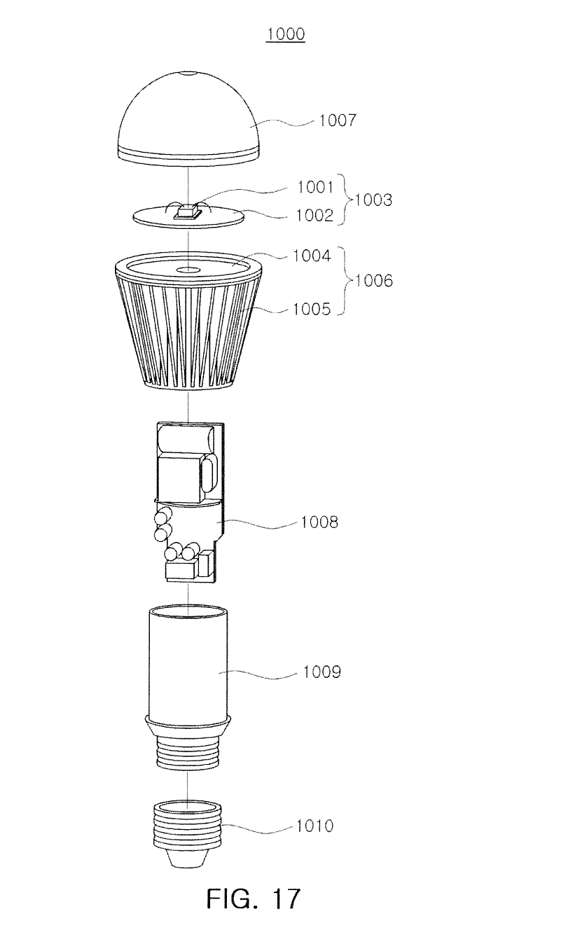

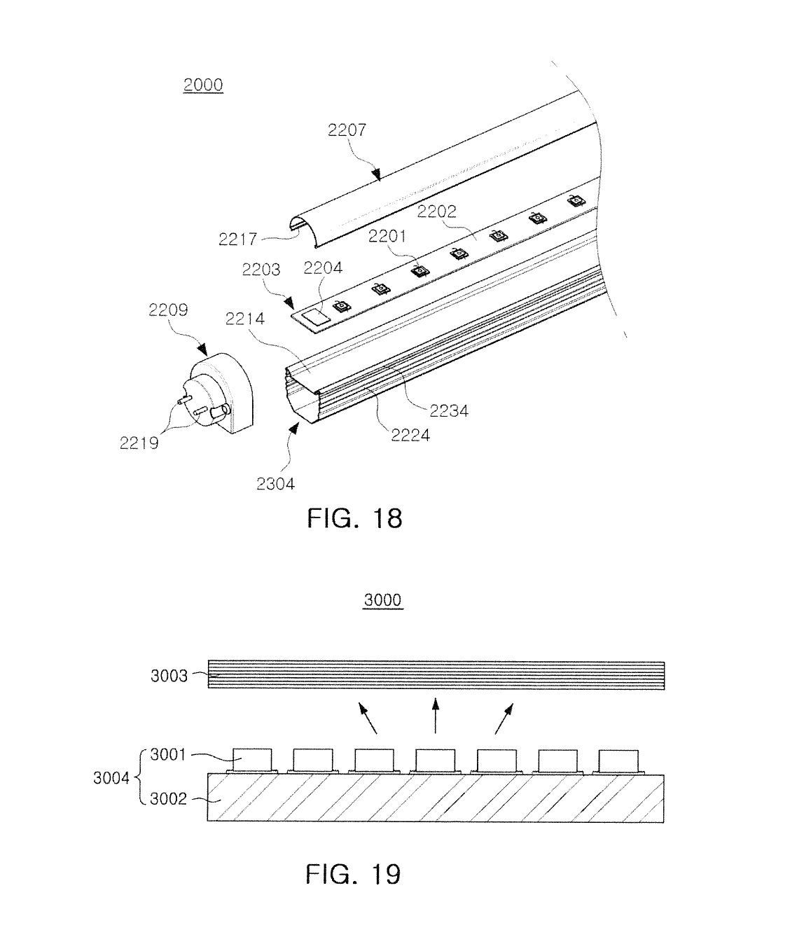

FIGS. 17 and 18 are views of examples of a lighting device in which a light emitting device according to an exemplary embodiment in the present disclosure is employed.

With reference to an exploded perspective view of FIG. 17, a lighting device 1000 is exemplified as a bulb-type lamp, and may include a light emitting module 1003, a driver 1008, and an external connector 1010. Also, the lighting device 1000 may further include exterior structures such as an external housing 1006, an internal housing 1009, and a cover 1007. The light emitting module 1003 may include a light source 1001 and a mounting board 1002 on which the light source 1001 is mounted. Any one of the light emitting devices described in the previous exemplary embodiments maybe used as the light emitting module 1003. The light source 1001 maybe mounted on the mounting board 1002 by means of an adhesive member, and the adhesive member may have a scattering pattern.

In addition, the light emitting module 1003 may include the external housing 1006 serving as a heat dissipation part, and the external housing 1006 may include a heat dissipation plate 1004 disposed to be in direct contact with the light emitting module 1003 and heat dissipation fins 1005 surrounding the side surface of the external housing 1006 so as to enhance heat dissipation. In addition, the lighting device 1000 may include the cover 1007 disposed above the light emitting module 1003 and have a convex lens shape. The driver 1008 may be installed in the internal housing 1009 and connected to the external connector 1010, such as a socket structure, to receive power from an external power source. Also, the driver 1008 may serve to convert the received power into power appropriate for driving the light source 1001 of the light emitting module 1003, and provide the converted power thereto. For example, the driver 1008 may be provided as an AC-DC converter, a rectifying circuit, or the like.

Meanwhile, a lighting device 2000 in which a light emitting device according to an exemplary embodiment is employed may be a bar-type lamp as illustrated in FIG. 18. Although not limited hereto, the lighting device 2000 may have a shape similar to that of a fluorescent lamp to replace a conventional fluorescent lamp, and may emit light having optical characteristics similar to those of a fluorescent lamp.

Referring to an exploded perspective view of FIG. 18, the lighting device 2000 according to the present exemplary embodiment may include a light emitting module 2203, a body 2304, and a driver 2209. The lighting device 2000 may further include a cover 2207 covering the light emitting module 2203.

The light emitting module 2203 may include a mounting board 2202 and a plurality of light sources 2201 mounted on the mounting board 2202. Any one of the light emitting devices described in the previous exemplary embodiments may be used as the light emitting module 2203. The light source 2201 may be mounted on the mounting board 2202 by means of an adhesive member, and the adhesive member may have a scattering pattern.

The body 2304 may allow the light emitting module 2203 to be fixed to one surface thereof. The body 2304, a type of support structure, may include a heat sink. The body 2304 may be formed of a material having excellent heat conductivity to dissipate heat generated by the light emitting module 2203 externally. For example, the body 2304 may be formed of a metal, but the material of the body 2304 is not limited thereto.

The body 2304 may have an elongated bar-like shape corresponding to the shape of the mounting board 2202 of the light emitting module 2203. A recess 2214 may be formed in one surface of the body 2304 in which the light emitting module 2203 is mounted, in order to accommodate the light emitting module 2203 therein.

A plurality of heat dissipation fins 2224 may protrude from at least one outer surface of the body 2304 to dissipate heat. A stopping recess 2234 may be formed in at least one end of the outer surface positioned in an upper portion of the recess 2214, and extend in a length direction of the body 2304. The cover 2207 may be fastened to the stopping recesses 2234.

At least one of end portions of the body 2304 in the length direction thereof may be open, so the body 2304 may have a pipe structure with at least end portion thereof open.

The driver 2209 may be fastened to at least one open end portion of the body 2304 in the length direction to supply driving power to the light emitting module 2203. In the present exemplary embodiment, it is illustrated that at least one end portion of the body 2304 is open, so the driver 2209 is disposed in at least one end portion of the body 2304. The driver 2209 may be fastened to at least one open end portion of the body 2304 to cover the same. The driver 2209 may include electrode pins 2219 protruding outwardly.

The cover 2207 maybe fastened to the body 2304 to cover the light emitting module 2203. The cover 2207 may be formed of a material allowing light to be transmitted therethrough.

The cover 2207 may have a curved surface having a semicircular shape to allow light to be uniformly irradiated externally on the whole. A protrusion 2217 may be formed in a length direction of the cover 2207 on the bottom of the cover 2207 fastened to the body 2304 so as to be engaged with the stopping recess 2234 of the body 2304.

In the present exemplary embodiment, the cover 2207 has a semicircular shape, but the shape of the cover 2207 is not limited thereto. For example, the cover 2207 may have a flat quadrangular shape or may have any other polygonal shape. The shape of the cover 2207 may be variously modified according to designs of illumination for irradiating light.

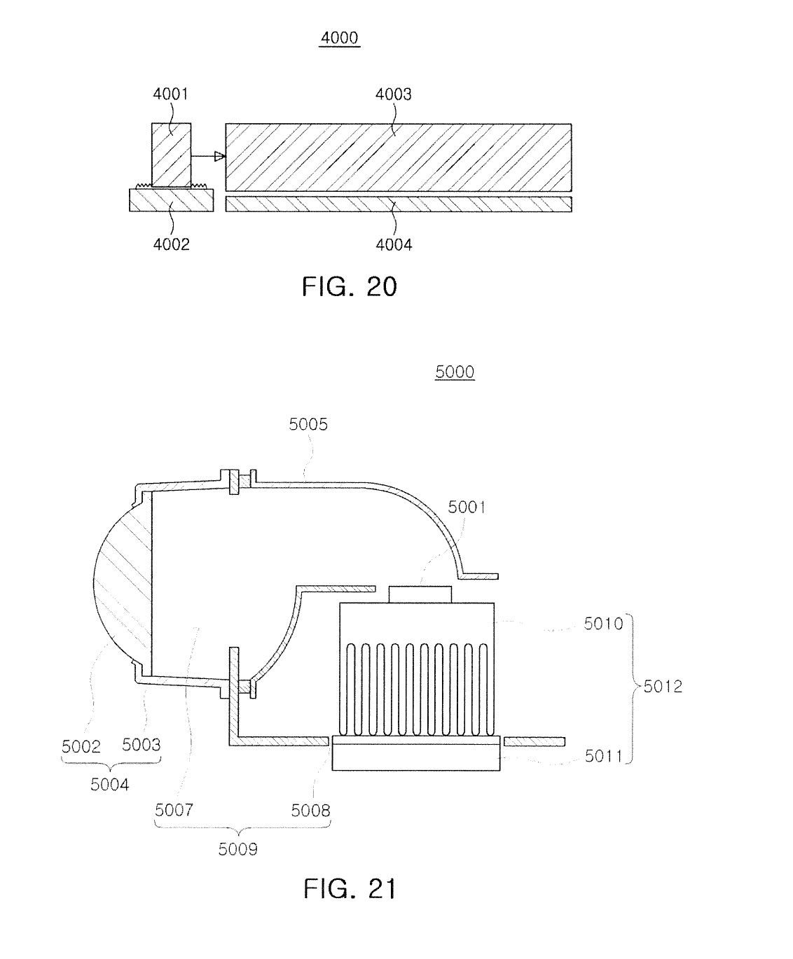

FIGS. 19 and 20 are views of examples of a backlight unit in which a light emitting device according to an exemplary embodiment is employed.

With reference to FIG. 19, a backlight unit 3000 may include a light emitting module 3004 including a mounting board 3002 and at least one light source 3001, and at least one optical sheet 3003 disposed thereabove. Any one of the light emitting devices described in the previous exemplary embodiments may be used as the light emitting module 3004. The light source 3001 may be mounted on the mounting board 3002 by means of an adhesive member, and the adhesive member may have a scattering pattern.

The light source 3001 in the backlight unit 3000 of FIG. 19 emits light upwardly, i.e., toward a liquid crystal display (LCD) disposed thereabove, whereas a light source 4001 mounted on a mounting board 4002 in a backlight unit 4000 according to another embodiment illustrated in FIG. 20 emits light laterally, and the light is incident to a light guide plate 4003 such that the backlight unit 4000 may serve as a surface light source. The light travelling to the light guide plate 4003 may be emitted upwardly and a reflective layer 4004 may be disposed below the light guide plate 4003 in order to improve light extraction efficiency.

FIG. 21 is a view of an example of a headlamp in which a light emitting device according to an exemplary embodiment is employed.

Referring to FIG. 21, a headlamp 5000 used as a vehicle lamp, or the like, may include a light emitting module 5001, a reflective part 5005, and a lens cover part 5004. The lens cover part 5004 may include a hollow guide 5003 and a lens 5002. Any one of the light emitting devices described in the previous exemplary embodiments may be used as the light emitting module 5001.

The headlamp 5000 may further include a heat dissipation part 5012 externally dissipating heat generated by the light emitting module 5001. In order to effectively dissipate heat, the heat dissipation part 5012 may include a heat sink 5010 and a cooling fan 5011.

Also, the headlamp 5000 may further include a housing 5009 fixedly supporting the heat dissipation part 5012 and the reflective part 5005, and the housing 5009 may include a central hole 5008 formed in one surface thereof, to which the heat dissipation part 5012 is coupled.

The housing 5009 may have a front hole 5007 formed in the other surface thereof integrally connected to one surface thereof and bent in a right angle direction. The reflective part 5005 may be fixed to the other surface of the housing 5009 so as to be positioned above the light emitting module 5001. Accordingly, light generated in the light emitting module 5001 may be reflected by the reflective part 5005 and pass through the front hole 5007 so as to be emitted externally.

As set forth above, a light emitting device according to exemplary embodiments of the present disclosure has improved luminous efficiency.

While exemplary embodiments have been shown and described above, it will be apparent to those skilled in the art that modifications and variations could be made without departing from the scope of the present invention as defined by the appended claims.

What is claimed is:

1. A light emitting device comprising:
a mounting board;
an adhesive member disposed on the mounting board and having a first surface adjacent to the mounting board and a second surface opposing the first surface; and
a light emitting element disposed on the second surface of the adhesive member,
wherein the second surface of the adhesive member has a first region on which the light emitting element is disposed and a second region on which a scattering pattern is provided to scatter light emitted by the light emitting element.

2. The light emitting device of claim 1, wherein the scattering pattern includes an uneven surface having irregular surface roughness.

3. The light emitting device of claim 2, wherein the surface roughness (RMS) of the uneven surface ranges from approximately 0.1 μm to 1.5 μm.

4. The light emitting device of claim 1, wherein the scattering pattern is extended in a direction from one side of the second surface to another side thereof, and includes a protrusion pattern and a recess pattern which are alternately arranged.

5. The light emitting device of claim 4, wherein at least one of an upper portion of the protrusion pattern and a lower portion of the recess pattern has at least one of a flat surface and a curved surface.

6. The light emitting device of claim 4, wherein an upper portion of the protrusion pattern has a pointed edge.

7. The light emitting device of claim 4, wherein a lower portion of the recess pattern has a V-like recess.

8. The light emitting device of claim 4, wherein at least one of an upper portion of the protrusion pattern and a lower portion of the recess pattern includes an uneven surface having irregular surface roughness.

9. The light emitting device of claim 1, wherein the scattering pattern includes an embossing pattern disposed on the second surface, the embossing pattern having at least one of a polypyramidal shape, a truncated polypyramidal shape, a conical shape, a truncated conical shape, and a dome shape.

10. The light emitting device of claim 1, wherein the scattering pattern includes an intaglio pattern disposed on the second surface, the intaglio pattern having at least one of a polypyramidal shape, a truncated polypyramidal shape, a conical shape, a truncated conical shape, and a dome shape.

11. The light emitting device of claim 1, wherein the adhesive member includes at least one material selected from the group consisting of an epoxy resin, a silicone resin, an acrylic resin, an oxetane resin, and combinations thereof.

12. The light emitting device of claim 1, further comprising an encapsulation part disposed on the mounting board and encapsulating the light emitting element.

13. The light emitting device of claim 12, wherein the encapsulation part includes a wavelength conversion material converting a wavelength of light emitted from the light emitting element to a different wavelength.

14. The light emitting device of claim 12, wherein a material of the encapsulation part and a material of the adhesive member have different refractive indices.

15. A light emitting device comprising:
a mounting board;
a light emitting element disposed on the mounting board; and
an adhesive member disposed between the mounting board and the light emitting element, and having a mounting portion on which the light emitting element is mounted and a peripheral portion which is disposed around the mounting portion,
wherein a scattering pattern is provided on the peripheral portion to scatter light emitted by the light emitting element.

16. A light emitting device, comprising:
a mounting board;
a light emitting element disposed on the mounting board; and
an adhesive member disposed between the mounting board and the light emitting element,
wherein a peripheral portion of the adhesive member that is not covered by the light emitting element includes a scattering pattern.

17. The light emitting device of claim 16, wherein a portion of the adhesive member that is covered by the light emitting element has a surface roughness different from that of the peripheral portion of the adhesive member.

18. The light emitting device of claim 16, wherein a thickness of the peripheral portion of the adhesive member varies in a direction crossing the light emitting device.

19. The light emitting device of claim 16, wherein the adhesive member includes at least one material selected from the group consisting of an epoxy resin, a silicone resin, an acrylic resin, an oxetane resin, and combinations thereof.

20. The light emitting device of claim 16, further comprising an encapsulation part disposed on the mounting board and covering the light emitting element and the adhesive layer,
wherein a material of the encapsulation part and a material of the adhesive member have different refractive indices.
